(19) United States
(12) Patent Application Publication
(10) Pub. No.: US 2006/0219284 A1
(43) Pub. Date: Oct. 5, 2006

(54) Thermoelectric conversion unit

(75) Inventors: Yuma Horio, Hamamatsu-shi (JP); Takahisa Tachibana, Hamamatsu-shi (JP); Naoki Kamimura, Hamamatsu-shi (JP)

Correspondence Address: DICKSTEIN SHAPIRO MORIN & OSHINSKY LLP, 1177 AVENUE OF THE AMERICAS (6TH AVENUE), 41 ST FL., NEW YORK, NY, 10036-2714, US

(73) Assignee: YAMAHA CORPORATION

(21) Appl. No.: 11/390,077

(22) Filed: Mar. 28, 2006

(30) Foreign Application Priority Data
Mar. 30, 2005 (JP) P2005-098448

(51) Int. Cl. H01L 35/30

(52) U.S. Cl. 136/205

(57) ABSTRACT

A thermoelectric conversion unit can easily be attached to and detached from a heater, in which lower electrodes are formed on the upper surface of a lower substrate, placed in opposition to an upper substrate, on the lower surface of which are formed upper electrodes; end faces of thermoelectric elements are bonded to both the electrodes to form a thermoelectric conversion module. A heat-absorbing member having a protruding engagement portion is installed on one of the substrates of the thermoelectric conversion module, and a heat-releasing member is installed on the other substrate, to form a thermoelectric conversion portion. A heat-conducting portion having a engagement hole portion is installed on the outer peripheral surface of a lamp, to form the light-source lamp portion. By engaging the protruding engagement portion with the engagement hole portion, the light-source lamp portion can be detachably attached to the thermoelectric conversion portion. The reflector, heat-absorbing member and heat-releasing member are formed from aluminum or an aluminum alloy.

### BACKGROUND OF THE INVENTION

1. Field of the Invention

This invention relates to a thermoelectric conversion unit having a thermoelectric conversion module, which uses waste heat of a heat-generating body to generate electricity.

Priority is claimed on Japanese Patent Application No. 2005-98448, filed Mar. 30, 2005, the content of which is incorporated herein by reference.

2. Description of Related Art

In the prior art, thermoelectric conversion modules which utilize the Peltier effect to perform thermoelectric conversion have been employed in heating and cooling equipment, in electric generators, and similar. Such thermoelectric conversion modules are configured by forming a plurality of electrodes at prescribed locations on the opposing inside surfaces of a pair of insulating substrates, and by soldering the upper and lower ends of thermoelectric elements to the opposing electrodes, to fix in place a plurality of thermoelectric elements between the pair of insulating substrates. Such a thermoelectric conversion module is for example fastened to the outer wall of a lamp, and by utilizing the power generated by the temperature difference between one insulating substrate, heated by the lamp, and the other insulating substrate, another device can be operated (Japanese Unexamined Patent Application, First Publication No. 2004-312986).

When a thermoelectric conversion module is mounted on a heater such as a lamp which, due to use over a prescribed length of time, has reached the end of its service life and can no longer be used, the need arises for the lamp to be detached from the thermoelectric conversion module and other main components and replaced each time the prescribed length of time has elapsed. However, because thermoelectric conversion modules of the prior art are not designed taking such replacement into consideration, there has been the problem that either replacement is not possible, or the replacement involves troublesome and complex tasks.

### SUMMARY OF THE INVENTION

A first aspect of the present invention is a thermoelectric conversion unit including a thermoelectric conversion module and a heater, in which the thermoelectric conversion module is attached to the heater to generate electric power using heat from the heater, wherein: the thermoelectric conversion module includes: a pair of insulating units placed in opposition; multiple electrodes formed at predetermined locations on opposing inside surfaces of the pair of insulating units; multiple thermoelectric elements having end faces connected to the electrodes on both the opposing inside surfaces; a heat-absorbing unit attached to one of the insulating units; and a heat-releasing unit attached to the other insulating unit; the thermoelectric conversion unit includes an attachment/detachment unit for attaching detachably the heat-absorbing unit to the heater; the heater heats the insulating unit to which the heat-absorbing unit is attached; and the thermoelectric conversion unit generates electric power by using temperature difference arisen between the end portion of the insulating units to which the heat absorbing unit is attached and the end portion of the insulating unit to which the heat-releasing unit is attached.

A second aspect of the present invention is the thermoelectric conversion unit described above, wherein the attachment/detachment unit includes a protruding portion and a hole portion; the protruding portion or the hole portion is provided at the heat-absorbing unit; the hole portion or the protruding portion is provided on a side of the heater; and the protruding portion and the hole portion are engaged.

A third aspect of the present invention is the thermoelectric conversion unit described above, wherein: a heat-conducting portion is formed on the surface of the heater; and the attachment/detachment mechanism is provided on the heat-conducting portion and on said heat-absorbing member.

A fourth aspect of the present invention is the thermoelectric conversion unit described above, wherein: the heater is a light-source lamp; and the heat-conducting portion is a reflector forming an outer-wall portion of the light-source lamp.

A fifth aspect of the present invention is the thermoelectric conversion unit described above, wherein the reflector is formed from aluminum or an aluminum alloy.

A sixth aspect of the present invention is the thermoelectric conversion unit described above, wherein: the heat-absorbing unit or the heat-releasing unit is formed from aluminum or an aluminum alloy.

A seventh aspect of the present invention is the thermoelectric conversion unit described above, wherein: the heat-absorbing unit or said heat-releasing unit is formed from a resin containing a metal filler.

### BRIEF DESCRIPTION OF THE DRAWINGS

FIG. 1 shows in summary the configuration of a thermoelectric conversion unit of a first embodiment of the present invention;

FIG. 2 is an oblique view of a thermoelectric conversion module;

FIG. 3 is a front view of a thermoelectric conversion module;

FIG. 4 is a front view showing the light-source lamp of the thermoelectric conversion unit of FIG. 1;

FIG. 5 shows in summary the configuration of the thermoelectric conversion unit of a second embodiment of the present invention;

FIG. 6 shows in summary the configuration of the thermoelectric conversion unit of a third embodiment of the present invention;

FIG. 7 shows in summary the configuration of the thermoelectric conversion unit of a fourth embodiment of the present invention;

FIG. 8 shows in summary the configuration of the thermoelectric conversion unit of a fifth embodiment of the present invention;

FIG. 9 shows in summary the configuration of the thermoelectric conversion unit of a sixth embodiment of the present invention;

FIG. 10 is a front view showing the thermoelectric conversion unit of Comparison Example 1;

FIG. 11 is a front view showing the state in which heat insulating material is removed from the thermoelectric conversion unit of FIG. 10;

FIG. 12 is a front view showing the state in which the thermoelectric conversion module and radiator fins are removed from the state of FIG. 11;

FIG. 13 is a front view showing the state in which the lamp is removed from the heat insulating member in the state of FIG. 12;

FIG. 14 shows in summary the configuration of a state in which the thermoelectric conversion unit of Embodiments 1 and 2 is attached to a light-source lamp portion; and,

FIG. 15 is a front view showing the light-source lamp portion from which the thermoelectric conversion portion shown in FIG. 14 is removed.

### DETAILED DESCRIPTION OF THE INVENTION

### First Embodiment

Hereinafter, a first embodiment of a thermoelectric conversion unit of the present invention is explained in detail, referring to the drawings. FIG. 1 shows a thermoelectric conversion unit Y1 of this embodiment. This thermoelectric conversion unit Y1 is provided in a device having a heater such as, for example, a projector device, and includes a thermoelectric conversion portion 10 mounted on the device main unit, and a light-source lamp portion 20 as the heater of the present invention. The light-source lamp 20 can be detachably attached to the device main unit and to the thermoelectric conversion portion 10.

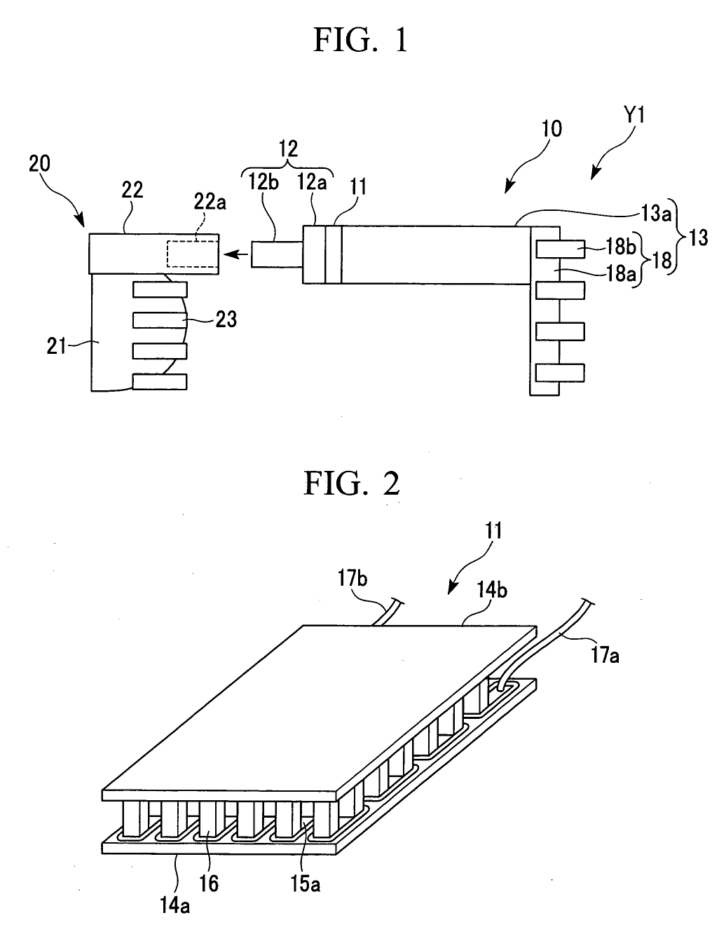

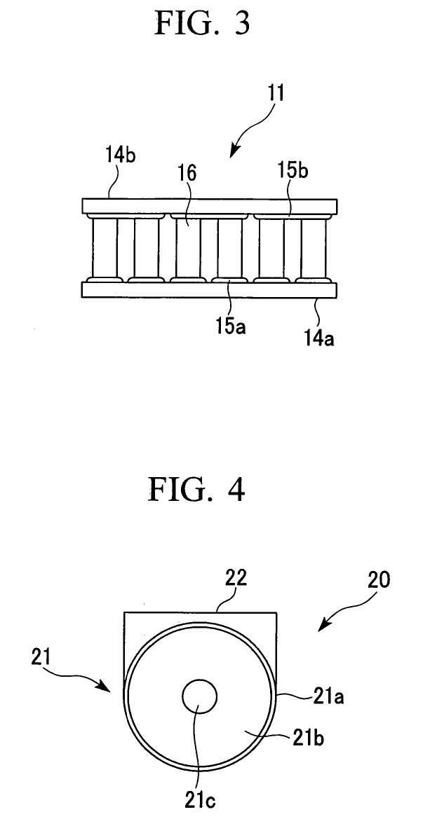

The thermoelectric conversion portion 10 is configured by mounting a heat insulating member 12 on one surface of the thermoelectric conversion module 11, and mounting a radiator member 13 on the other surface of the thermoelectric conversion module 11. As shown in FIG. 2 and FIG. 3, the thermoelectric conversion module 11 has a pair of insulating substrates, which are a lower substrate 14a and an upper substrate 14b; lower electrodes 15a are formed in prescribed locations on the upper surface of the lower substrate 14a, and upper electrodes 15b are formed in prescribed locations on the lower surface of the upper substrate 14b. Thermoelectric elements 16, which are chips with a rectangular solid shape, have their lower end faces fixed by soldering to the lower electrodes 15a and their upper end faces fixed by soldering to the upper electrodes 15b, to integrally join the lower substrate 14a and the upper substrate 14b.

The lower electrodes 15a and the upper electrodes 15b are mounted and shifted by a distance substantially equal to one width of a thermoelectric element 16, and the thermoelectric elements 16 are placed at fixed intervals in the longitudinal and lateral directions. The upper-end faces of two thermoelectric elements 16 are bonded to each of the upper electrodes 15b on the upper substrate 14b, and there are both modules in which the lower electrodes 15a on the lower substrate 14a are bonded to the lower-end face of only one thermoelectric element 16 and in which the lower electrodes are bonded to the lower-end faces of two thermoelectric elements 16. The thermoelectric elements 16 are connected between the lower substrate 14a and the upper substrate 14b so as to be electrically connected via the lower electrodes 15a and upper electrodes 15b.

Lower electrodes 15a bonded to the lower-end face of only one thermoelectric element 16 are provided in the corner portions in two locations on one side of the lower substrate 14a, and lead wires 17a, 17b are mounted on these lower electrodes 15a. The thermoelectric conversion module 11 can be electrically connected to external equipment via these lead wires 17a, 17b. The lower substrate 14a and upper substrate 14b are formed from alumina sheets; the thermoelectric elements 16 consist of P-type elements and N-type elements formed from a bismuth-tellurium alloy. A thermoelectric conversion module 11 configured in this way has the lower substrate 14a positioned in the front (on the side of the light-source lamp 20) as the heat-absorbing side, and the upper substrate 14b positioned to the rear as the heat-releasing side.

The heat-absorbing member 12 consists of aluminum, and is configured from a base portion 12a in a square sheet shape, fixed to the lower substrate 14a of the thermoelectric conversion module 11, and a pair of protruding engagement portions 12b (only one of which is shown), as protruding portions of this invention protruding from the open surface (front surface) of the base portion 12a perpendicularly to the base portion 12a. The protruding engagement portions 12b are provided, with an interval, on both sides of the center portion in the vertical direction (the portions on both sides in the anteroposterior direction in FIG. 1) in the open surface of the base portion 12a. The heat-releasing member 13 is configured from a heat-absorbing portion 13a, fixed to the upper substrate of the thermoelectric conversion module 11, and heat-releasing fins 18, fixed to the rear-end portion of the heat-absorbing portion 13a. The heat-absorbing portion 13a is configured from a square and rod-shaped aluminum.

The heat-releasing fins 18 are formed from aluminum, and consist of multiple protrusions 18b provided at predetermined intervals on the rear surface of a square sheet-shaped substrate 18a. These heat-releasing fins 18 are placed so as to extend below the heat-absorbing portion 13a, in a state in which the front end of the substrate 18a is fixed to the rear-end surface of the heat-absorbing portion 13a. The heat-releasing fins 18 improve the heat-releasing properties by increasing the surface area through the multiple protrusions 18b provided, so as to effectively release to the outside environment heat which has been conducted from the thermoelectric conversion module 11 via the heat-absorbing portion 13a. By this means, the temperature difference between the lower-substrate 14a and the upper substrate 14b of the thermoelectric conversion module 11 is increased, and a greater amount of electric power is generated by the thermoelectric conversion module 11.

The light-source lamp portion 20 is configured from a lamp 21 and heat-conducting portion 22. As shown in FIG. 4, the reflector 21a constituting the outer surface of the lamp 21 is substantially a dome shape formed from aluminum which is formed into an aperture with a circular shape in front; the side surface becomes narrower toward the rear end, and the rear-end portion is closed. Transparent glass 21b is provided in the aperture portion on the front of the reflector 21a, and a vessel light source 21c is provided in the center at the interior rear end within the reflector 21a. The vessel light source 21c consists of an ultra-high pressure mercury lamp, the temperature of which rises to 900° C. to 1000° C. approximately when lit. At this time, the temperature of the reflector 21a rises to from 230° C. to 300° C.

On the outer surface of the reflector 21a, substantially from the center portion to the rear-end portion in the circumferential direction, fin portions 23 for heat release are provided at fixed intervals and which are extending from front to back. The heat-conducting portion 22 is formed from a block of aluminum installed along the upper surface of the lamp 21, with length in the width direction and length in the anteroposterior direction longer than the length in the height direction. On both sides in the width direction at the rear-end surface of the heat-conducting portion 22 are formed a pair of engagement hole portions 22a (only one of which is shown), into which the pair of protruding engagement portions 12b of the heat-absorbing member 12 can be inserted.

When using a thermoelectric conversion unit Y1 configured as described above, the light-source lamp portion 20 is mounted on the thermoelectric conversion portion 10 while inserting the protruding engagement portions 12b into the respectively engagement hole portions 22a. At this time, grease or similar with excellent heat-conduction properties is applied to the surface of the protruding engagement portions 12b. By this means the thermal resistance can be reduced, and the performance of heat conduction from the heat-conducting portion 22 to the heat-absorbing member 12 can be improved. Also at this time, the light-source lamp portion 20 is not merely mounted on the thermoelectric conversion portion 10, but also it is engaged with the holding portion (not shown) of the device on which the thermoelectric conversion unit Y1 is provided, so that held by this holding portion as well.

By supplying electric power from outside to the device with the light-source lamp 20 attached in this way, the lamp 21 is lighted. At this time, heat generated by the lamp 21 is conveyed from the reflector 21a, via the heat-conducting portion 22 and heat-absorbing member 12, to the lower substrate 14a of the thermoelectric conversion module 11, to heat the lower substrate 14a. By this means, a temperature difference arises between the lower substrate 14a and the upper substrate 14b of the thermoelectric conversion module 11, and the thermoelectric conversion module 11 generates electricity.

At this time, the upper substrate 14b of the thermoelectric conversion module 11 is cooled by the heat-absorbing portion 13a and heat-releasing fins 18, so that the temperature difference between the thermoelectric lower substrate 14a and the upper substrate 14b of the thermoelectric conversion module 11 is further increased, and the electric power generated by the thermoelectric conversion module 11 is even greater. The power generated by this thermoelectric conversion module 11 is used to operate an additional device, such as for example a fan, provided in the thermoelectric conversion unit Y1. The lamp 21 is prevented from heating to temperatures above a predetermined temperature by the heat-absorbing action of the heat-conducting portion 22 and fin portion 23, and by this means its service life is prolonged.

Thus in the thermoelectric conversion unit yl of this embodiment, a heat-absorbing member 12 is installed on the lower substrate 14a on the side of the light-source lamp portion 20 of the thermoelectric conversion module 11, and a heat-releasing member 13, consisting of a heat-absorbing portion 13a and heat-releasing fins 18, is installed on the upper substrate 14b of the thermoelectric conversion module 11. Further, protruding engagement portions 12b are provided on the heat-absorbing member 12, and a heat-conducting portion 22, provided with engagement hole portions 22a into which the protruding engagement portions 12b can be inserted, is installed on the reflector 21a of the lamp 21. By causing the protruding engagement portions 12b to be inserted into the respective engagement hole portions 22a, the light-source lamp portion 20 can be installed on the thermoelectric conversion portion 10. Hence heat conduction from the lamp 21 to the thermoelectric conversion module 11 is performed efficiently, and heat conduction from the thermoelectric conversion module 11 to the heat-releasing member 13 is performed efficiently, so that the thermoelectric conversion module 11 can generate electricity efficiently.

Moreover, attachment and detachment of the light-source lamp portion 20 to and from the thermoelectric conversion portion 10 are easily accomplished, involving merely inserting the protruding engagement portions 12b into the engagement hole portions 22a, and pulling of the light-source lamp portion 20 from the thermoelectric conversion portion 10. Further, the heat-absorbing member 12, heat-releasing member 13, reflector 21a, and heat-conducting portion 22 are formed from aluminum, which has good heat-conducting properties, and a grease layer is formed between the protruding engagement portions 12b and the engagement hole portions 22a, so that heat is conducted efficiently between the various portions from which the thermoelectric conversion unit Y1 is configured. Moreover, the weight of the devices making up the thermoelectric conversion unit Y1 is reduced.

### Second Embodiment

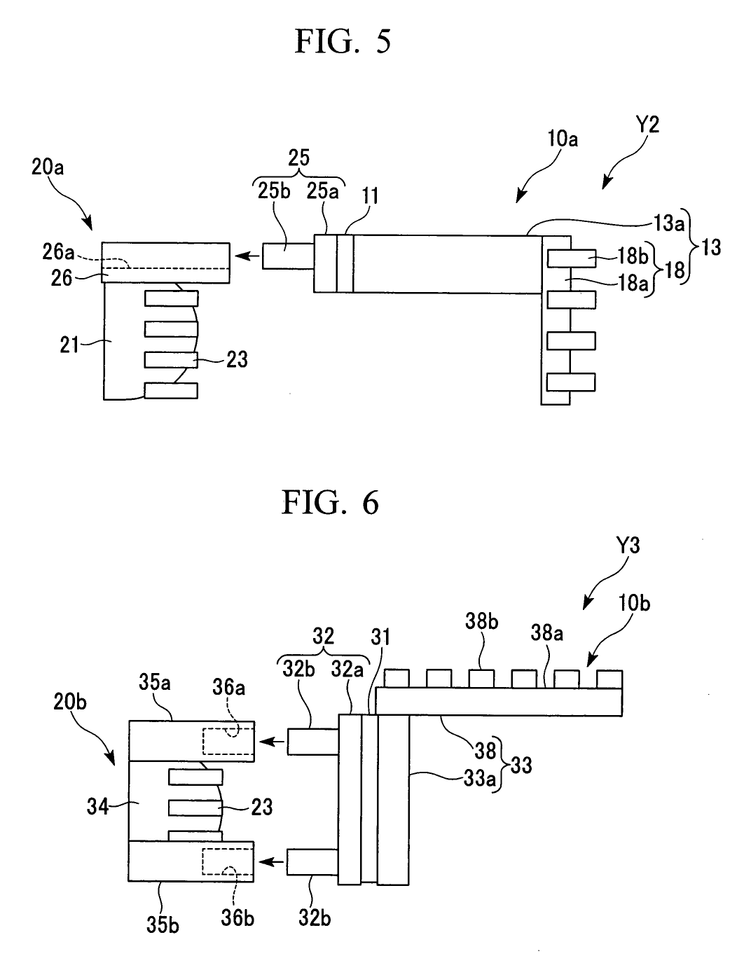

FIG. 5 shows the thermoelectric conversion unit Y2 of a second embodiment of the present invention. In this thermoelectric conversion unit Y2, the protruding engagement portions 25b of the heat-absorbing member 25 of the thermoelectric conversion portion 10a are provided at intervals on both sides of the upper-end side portion in the open surface of the base portion 25a. And, the engagement hole portions 26a of the heat-conducting portion 26 of the light-source lamp portion 20a are groove-shaped hole portions with openings in the rear-end face and upper face. Other portions of the thermoelectric conversion unit Y2 are the same as in the above-described thermoelectric conversion unit Y1. Hence the same symbols are assigned to the same portions, and explanations are omitted.

By means of this configuration, when the light-source lamp portion 20a is installed on the thermoelectric conversion portion 10a, rather than moving the light-source lamp portion 20a in the horizontal direction for attachment to the thermoelectric conversion portion 10a, the light-source lamp portion 20a can be moved upward from below to insert the protruding engagement portions 25b into the engagement hole portions 26a. And, when the light-source lamp portion 20a is removed from the thermoelectric conversion portion 10a, the light-source lamp portion 20a can be moved forward or downward to release the mating of the engagement hole portions 26a and the protruding engagement portions 25b. As a result, the light-source lamp portion 20a can easily be attached to and detached from the thermoelectric conversion portion 10a. Otherwise the advantageous results of action of the thermoelectric conversion unit Y2 are similar to those of the above-described thermoelectric conversion unit Y1.

### Third Embodiment

FIG. 6 shows the thermoelectric conversion unit Y3 of a third embodiment of the present invention. In this thermoelectric conversion unit Y3, the thermoelectric conversion module 31 of the thermoelectric conversion portion 10b is configured to have both front and back surfaces with large area, and the heat-absorbing member 32 and heat-absorbing portion 33a of the heat-releasing member 33 are also formed in sheet shape having area according to the surface of installation (front and back surfaces) of the thermoelectric conversion module 31. The protruding engagement portions 32b of the heat-absorbing member 32 are provided at a fixed interval in the four corners of the open surface of the base portion 32a. The heat-releasing fins 38 extend rearward perpendicularly to the heat-absorbing portion 33a in a state in which the front end of the lower face is fixed to the upper-end portion of the heat-absorbing portion 33a. The protrusions 38b of the heat-releasing fins 38 are provided on the upper face of the substrate 38a.

The heat-conducting portion of the light-source lamp 20b is formed from an upper heat-conducting portion 35a mounted along the upper face of the lamp 34, and a lower heat-conducting portion 35b mounted along the lower face of the lamp 34. engagement hole portions 36a, 36b, into which the protruding engagement portions 32b can be inserted, are formed on both sides in the cross direction (horizontal direction in FIG. 6) on the rear-end face of the upper heat-conducting portion 35a and lower heat-conducting portion 35b. Other portions of the thermoelectric conversion unit Y3 are the same as in the above-described thermoelectric conversion unit Y1. Hence the same symbols are assigned to the same portions, and explanations are omitted.

By means of this configuration, engagement of the light-source lamp 20b and thermoelectric conversion portion 10b can be performed more reliably, and the heat-conducting performance from the light-source lamp 20b to the thermoelectric conversion portion 10b is improved. Further, the protrusions 38b of the heat-releasing fins 38 are provided on the upper face of the substrate 38a, so that the effect of heat dissipation by the heat-releasing member 33 is also improved. Otherwise the advantageous results of action of the thermoelectric conversion unit Y3 are similar to those of the above-described thermoelectric conversion unit Y1.

### Fourth Embodiment

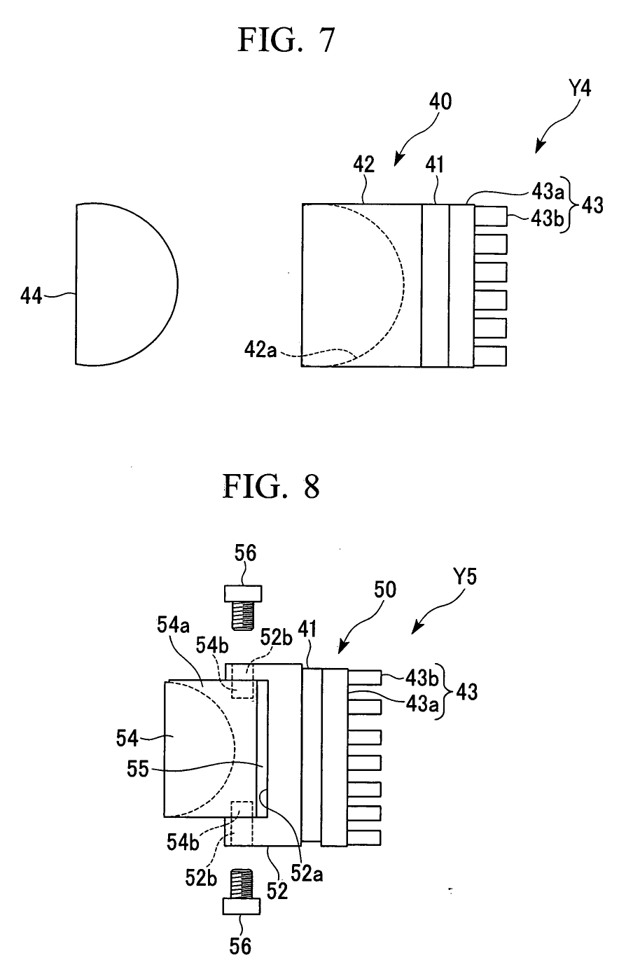

FIG. 7 shows the thermoelectric conversion unit Y4 of a fourth embodiment of the present invention. In this thermoelectric conversion unit Y4, the light-source lamp portion is formed solely from a lamp 44, without having a heat-conducting portion or fin portion. Further, the thermoelectric conversion portion 40 is formed from a thermoelectric conversion module 41, heat-absorbing member 42, and heat-releasing fins 43 having a heat-releasing member. This thermoelectric conversion module 41 has both front and rear faces of large area, and the heat-absorbing member 42 and heat-releasing fins 43 also have areas according to the installation surface of the thermoelectric conversion module 41.

A spherically-shaped housing concave portion 42a capable of housing the lamp 44 is formed in the face on the open side of the heat-absorbing member 42. The protrusions 43b of the heat-releasing fins 43 are provided on the rear face of the substrate 43a. Other portions of the thermoelectric conversion unit Y4 are the same as in the above-described thermoelectric conversion unit Y1. By means of this configuration, attachment and detachment of the lamp 44 onto and from the thermoelectric conversion portion 40 is easy. Further, because the area of contact between the lamp 44 and the heat-absorbing member 42 is large, the properties of heat conduction from the lamp 44 to the thermoelectric conversion portion 40 are improved. Otherwise the advantageous results of action of the thermoelectric conversion unit Y4 are similar to those of the above-described thermoelectric conversion unit Y1.

### Fifth Embodiment

FIG. 8 shows the thermoelectric conversion unit Y5 of a fifth embodiment of the present invention. In this thermoelectric conversion unit Y5, the light-source lamp portion is configured solely from a lamp 54, without having a heat-conducting portion or fin portion, and the rear-side portion of the reflector 54a of the lamp 54 is formed into a square block shape. Screw holes 54b are formed in the top-face center and bottom-face center of the rear-end portion of the reflector 54a.

The heat-absorbing member 52 of the thermoelectric conversion portion 50 is configured from a block with a housing concave portion 52a, capable of housing the rear-end side portion of the reflector 54a, formed in the front-end face; a heat-conducting sheet 55 is placed in the rear end within the housing concave portion 52a. Screw-insertion holes 52b, which penetrate the housing concave portion 52a from the outer surface, are provided in the upper center and lower center of the front-end side portion of the heat-absorbing member 52. By placing the reflector 54a of the lamp 54 into this housing concave portion 52a, passing screws 56 through the screw-insertion holes 52b, and engaging the tips thereof with the screw holes 54b of the reflector 54a, the lamp 54 is mounted onto the thermoelectric conversion portion 50.

Other portions of the thermoelectric conversion unit Y5 are the same as in the above-described thermoelectric conversion unit Y4. Hence the same symbols are assigned to the same portions, and explanations are omitted. As a result of this configuration, the lamp 54 is mounted more firmly onto the thermoelectric conversion portion 50. Further, because a heat-conducting sheet 55 is placed between the lamp 54 and the heat-absorbing member 52, the properties of heat conduction from the lamp 54 to the thermoelectric conversion portion 50 are improved. Otherwise the advantageous results of action of the thermoelectric conversion unit Y5 are similar to those of the above-described thermoelectric conversion unit Y4.

### Sixth Embodiment

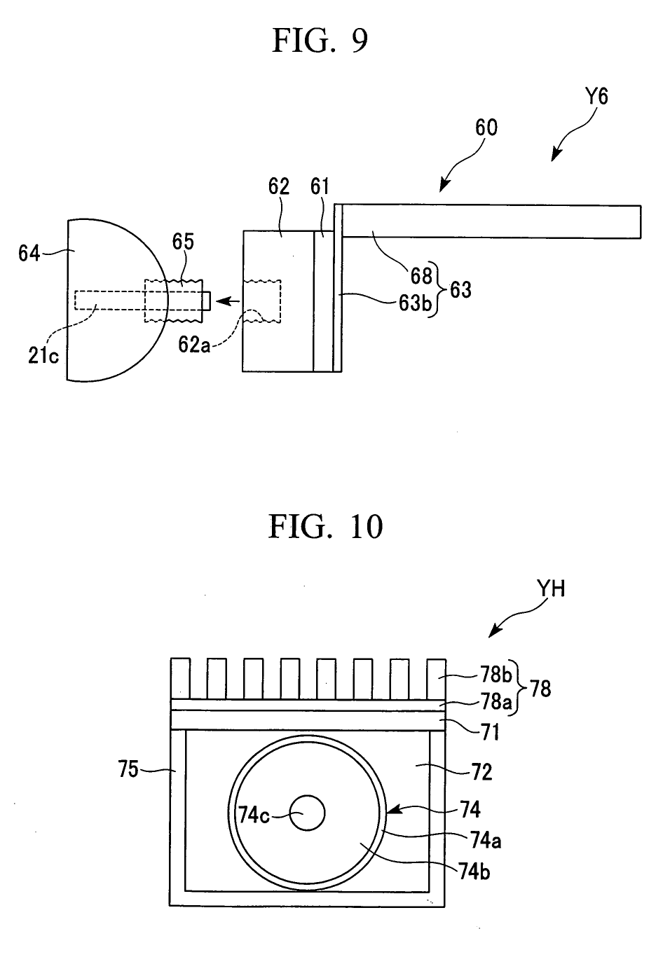

FIG. 9 shows the thermoelectric conversion unit Y6 of a sixth aspect of the present invention. In this thermoelectric conversion unit Y6, a bolt 65 is formed in the rear-end portion of the lamp 64 configuring the light-source lamp portion. Also, the thermoelectric conversion portion 60 is configured from a thermoelectric conversion module 61 having front and back faces with large-area, heat-absorbing member 62, and heat-releasing member 63. The heat-absorbing member 62 is configured from a block of rectangular shape, on the front-end face of which is formed a screw hole 62a capable of engaging with the bolt 65 on the lamp 64 to enable attachment and detachment.

The heat-releasing member 63 is configured from a thin sheet-shape heat-absorbing portion 63a and a rod-shaped supporting portion 68 which supports the thermoelectric conversion portion 60. The heat-absorbing portion 63a is fixed to the rear face of the thermoelectric conversion module 61 in a state in which the upper-end portion protrudes above the thermoelectric conversion module 61; the upper end of the rear face of the heat-absorbing portion 63a is fixed to the front-end face of the supporting portion 68. The supporting portion 68 constitutes one portion of the housing of the device onto which the thermoelectric conversion unit Y6 is mounted, and supports the lamp 64 via the heat-absorbing portion 63a and similar, while also absorbing waste heat from the lamp 64 via the heat-absorbing portion 63a and releasing the waste heat.

Other portions of the thermoelectric conversion unit Y6 are the same as in the above-described thermoelectric conversion unit Y4. Because of this configuration, installation of the lamp 64 on the thermoelectric conversion portion 60 can be performed still more reliably and firmly. Moreover, because a portion of the thermoelectric conversion portion 60 consists of the supporting portion 68, which is a portion of the device housing, the number of members is reduced and construction is simplified. Otherwise the advantageous results of action of the thermoelectric conversion unit Y6 are similar to those of the above-described thermoelectric conversion unit Y4.

Next, an Embodiment 1 was prepared as a thermoelectric conversion unit in which, in the thermoelectric conversion unit Y3 shown in FIG. 6, the reflector 21a, heat-absorbing member 32, and heat-releasing member 33 were formed from an aluminum alloy, and an Embodiment 2 was prepared as a thermoelectric conversion unit in which the reflector 21a in the thermoelectric conversion unit Y3 was formed from an aluminum alloy, and the heat-absorbing member 32 and heat-releasing member 33 were formed from a resin with metal filler. A thermoelectric conversion unit of the prior art, described below, was prepared as a Comparison Example 1, and tests were performed to compare the time required for replacement of the light-source lamp portion in each of the thermoelectric conversion units of the Embodiments 1 and 2 and the Comparison Example 1. Specifically, when replacing the light-source lamp portion 20b in Embodiments 1 and 2 and replacing the lamp 74 in Comparison Example 1, the time required to restore the original thermoelectric conversion unit was measured. As the Comparison Example 1, the thermoelectric conversion unit YH shown in FIG. 10 was used.

In the lamp 74 of this thermoelectric conversion unit YH, the reflector 74a is formed from glass, transparent glass 74b is mounted in the aperture portion thereof, and a tubular light source 74c is mounted at the center on the inside of the reflector 74a. A block-shape heat-absorbing member 72 is mounted so as to cover the outer peripheral surface of the lamp 74, and both side faces and the bottom face of this heat-absorbing member 72 are covered with adiabatic material 75. The thermoelectric conversion module 71 is mounted on the upper face of the heat-absorbing member 72, and heat-releasing fins 78 consisting of a substrate 78a and protrusions 78b are mounted on the upper face of the thermoelectric conversion module 71.

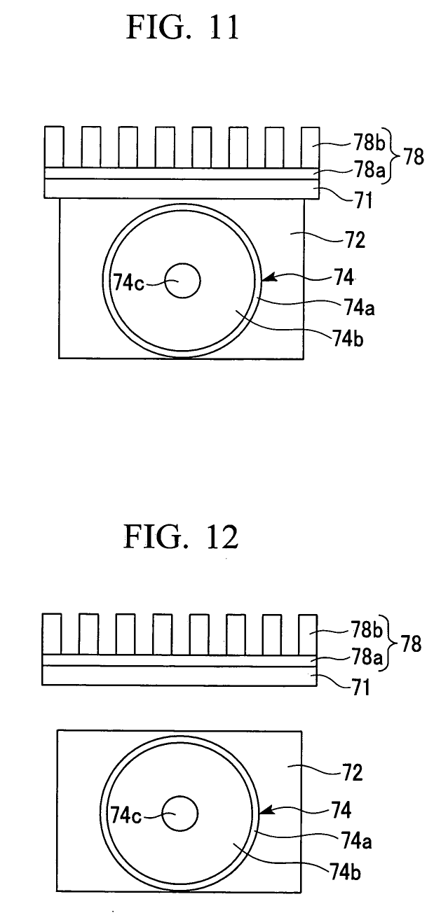

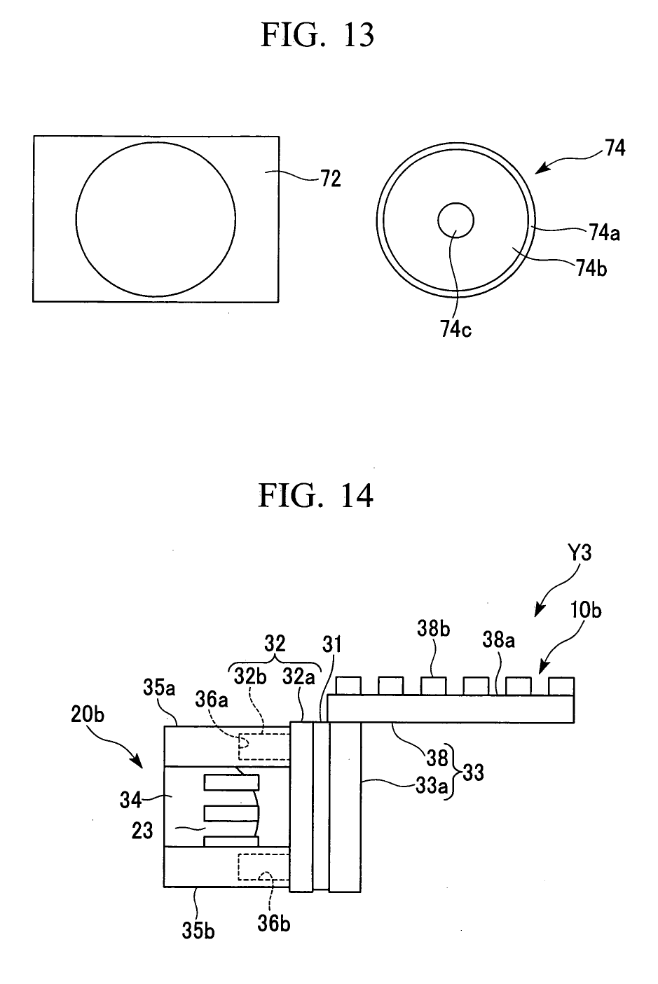

An operation to replace the lamp 74 in this thermoelectric conversion unit YH is performed according to the procedure shown in FIG. 10 through FIG. 13. First, the adiabatic material 75 is removed from the thermoelectric conversion unit YH in the state shown in FIG. 10, resulting in the state of FIG. 11. Then, the thermoelectric conversion module 71 and heat-releasing fins 78 are removed, while still attached to each other, from the heat-absorbing member 72, resulting in the state shown in FIG. 12. Next, the lamp 74 is removed from the heat-absorbing member 72, to obtain the state of FIG. 13. A lamp 74 for use in replacement is prepared, and by reassembling the thermoelectric conversion unit YH following the opposite order of that described above, moving in succession from the state of FIG. 13 to the state of FIG. 10, the replacement operation is completed. When the lamp 74 is inserted into the heat-absorbing member 72, grease is applied to the outer peripheral surface of the reflector 74a so that the surfaces of the heat-absorbing member 72 and reflector 74a are in close contact and thermal resistance is kept small.

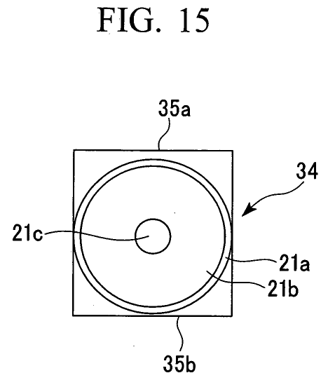

The operation to replace the lamp 34 in Embodiments 1 and 2 (thermoelectric conversion unit Y3) is performed according to the procedure shown in FIG. 14 and FIG. 15. First, the light-source lamp 20b is pulled forward from the thermoelectric conversion unit Y3 in the state shown in FIG. 14 to remove the lamp from the thermoelectric conversion portion 10b, resulting in the state of FIG. 6. At this time, the state of the light-source lamp portion 20b as seen from the front is as shown in FIG. 15. Then, a light-source lamp portion 20b with a lamp 34 for use in replacement is prepared, and by reassembling the thermoelectric conversion unit Y3 following the opposite order of that described above, moving in succession from the state of FIG. 15 to the state of FIG. 14, the replacement operation is completed. The results of these comparison tests are described in Table 1 below.

TABLE 1

| | Maximum | | |
|---|---|---|---|
| | temperature | | |
| | of reflector | | |
| | external wall | | |
| | (during | Time for lamp | |
| | use at 160 W) | replacement | Specifications |
| Comparison | 280° C. | 5 to 8 minutes | Glass reflector, |
| Example 1 | | | conventional |
| | | | construction |
| Embodiment | 190° C. | 30 to 40 seconds | Aluminum alloy |
| 1 | | | reflector, |
| | | | heat-absorbing |
| | | | member and heat- |
| | | | releasing member |
| | | | also of aluminum |
| | | | alloy |
| Embodiment | 220° C. | 30 to 40 seconds | Aluminum alloy |
| 2 | | | reflector, heat- |
| | | | absorbing member |
| | | | and heat- |
| | | | releasing member |
| | | | of resin with |
| | | | metal filler |

As a result, whereas in Comparison Example 1 from five to eight minutes were required for lamp replacement, in Embodiments 1 and 2 the time required for replacement of the lamp 34 was 30 to 40 seconds in both cases. From this result it is seen that by means of the thermoelectric conversion unit Y3 of Embodiments 1 and 2, which are thermoelectric conversion units of this invention, the time required for replacement of the lamp 34 can be greatly reduced compared with the conventional thermoelectric conversion unit YH. In the above-described Embodiments 1 and 2 and Comparison Example 1 a lamp with power consumption of 160 W is used; for reference, the maximum temperatures at the outer peripheral surface of the reflector of the lamp in each embodiment and example were measured. These results are also presented in Table 1.

As shown in Table 1, whereas in Comparison Example 1 the maximum temperature at the outer peripheral surface of the reflector 74a was 280° C., the maximum temperature at the outer peripheral surface of the reflector 21a in Embodiment 1 was 190° C., and the maximum temperature at the outer peripheral surface of the reflector in Embodiment 2 was 220° C. In general, the higher the temperature of a lamp, the shorter is the service lifetime, and cooling to keep a lower temperature will prolong the service lifetime. Hence from the test results it is seen that the service lifetime of the lamp 34 can be made longer in Embodiments 1 and 2 compared with Comparison Example 1.

Thermoelectric conversion units of the present invention are not limited to those in the above-described embodiments, and appropriate modifications can be made. For example, in the above-described embodiments and examples, the material used to form the heat-absorbing member 12 and similar and the heat-releasing member 13 and similar were aluminum, an aluminum alloy, or a resin with a metal filler; but the material used is not limited to these, and for example tough pitch copper, oxygen-free copper, or other materials with excellent thermal conductivity can be used. Also, when the heat-absorbing member 12 and similar and the heat-releasing member 13 and similar are formed from a resin with a metal filler, cast nylon, ultra-high molecular-weight polyethylene, polyacetal, or another engineering plastic, in which is dispersed metal particles of copper, aluminum, tin, zinc, bismuth, magnesium or similar or graphite particles, can be used. By this means, both improved thermal conduction and reduced weight can be achieved.

Further, the shapes, materials and similar of other portions used to configure a thermoelectric conversion unit of the present invention can also be modified appropriately. Also, devices onto which a thermoelectric conversion unit of this invention is to be installed are not limited to projector devices, and installation is possible on any device which uses a heater such as a lamp and generates heat. For example, use is possible with outdoor illumination, indoor illumination, automobiles, motorcycles, and other devices employing lights. Moreover, the heater is not limited to a lamp or light, but may be a white-light LED or similar, or may be a heater that does not emit light.

What is claimed is:

1. A thermoelectric conversion unit including a thermoelectric conversion module and a heater, in which the thermoelectric conversion module is attached to the heater to generate electric power using heat from the heater, wherein:
the thermoelectric conversion module comprises:
a pair of insulating units placed in opposition;
a plurality of electrodes formed at predetermined locations on opposing inside surfaces of the pair of insulating units;
a plurality of thermoelectric elements having end faces connected to the electrodes on both the opposing inside surfaces;
a heat-absorbing unit attached to one of the insulating units; and
a heat-releasing unit attached to the other insulating unit;
the thermoelectric conversion unit comprises an attachment/detachment unit for attaching detachably the heat-absorbing unit to the heater;
the heater heats the insulating unit to which the heat-absorbing unit is attached; and
the thermoelectric conversion unit generates electric power by using temperature difference arisen between the end portion of the insulating units to which the heat absorbing unit is attached and the end portion of the insulating unit to which the heat-releasing unit is attached.

2. The thermoelectric conversion unit according to claim 1, wherein
the attachment/detachment unit comprises a protruding portion and a hole portion;
the protruding portion or the hole portion is provided at the heat-absorbing unit;
the hole portion or the protruding portion is provided on a side of the heater; and
the protruding portion and the hole portion are engaged.

3. The thermoelectric conversion unit according to claim 1, wherein:
a heat-conducting portion is formed on the surface of the heater; and
the attachment/detachment mechanism is provided on the heat-conducting portion and on said heat-absorbing member.

4. The thermoelectric conversion unit according to claim 3, wherein:
the heater is a light-source lamp; and
the heat-conducting portion is a reflector forming an outer-wall portion of the light-source lamp.

5. The thermoelectric conversion unit according to claim 4, wherein the reflector is formed from aluminum or an aluminum alloy.

6. The thermoelectric conversion unit according to claim 1, wherein:
the heat-absorbing unit or the heat-releasing unit is formed from aluminum or an aluminum alloy.

7. The thermoelectric conversion unit according to claim 1, wherein:
the heat-absorbing unit or said heat-releasing unit is formed from a resin containing a metal filler.
